(19) United States
(12) Patent Application Publication
(10) Pub. No.: US 2005/0161766 A1
(43) Pub. Date: Jul. 28, 2005

(54) Semiconductor device and method for fabricating the same

(75) Inventors: Motonobu Sato, Kawasaki (JP); Toyoji Sawada, Kawasaki (JP); Satoshi Otsuka, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/872,543

(22) Filed: Jun. 22, 2004

(30) Foreign Application Priority Data
Jan. 23, 2004 (JP) 2004-15259

(51) Int. Cl. H01L 21/82; H01L 27/10

(52) U.S. Cl. 257/529; 257/209; 438/128; 438/132

(57) ABSTRACT

The semiconductor device comprises an inter-layer insulating film 18 formed over a substrate 10, a fuse 26 buried in the inter-layer insulating film 18, and a cover film 30 formed over the inter-layer insulating film 18 and having an opening formed therein down to the fuse 26. The inter-layer insulating film 18 is formed in contact with the side wall of the fuse 26 in the opening, whereby the fuse 26 is supported with the inter-layer insulating film 18 to thereby prevent the pattern collapse and pattern scatter. The wide scatter of the fuses can be prevented, and the fuses can be arranged in a small pitch.

### CROSS-REFERENCE TO RELATED APPLICATIONS

This application is based upon and claims the benefit of priority from the prior Japanese Patent Application No. 2004-015259, filed on Jan. 23, 2004, the entire contents of which are incorporated herein by reference.

### BACKGROUND OF THE INVENTION

The present invention relates to a semiconductor device and a method for fabricating the same, more specifically a semiconductor device which permits the circuits to be reconstituted by disconnecting fuses by irradiating laser beams and a method for fabricating the semiconductor device.

Semiconductor devices, e.g., memory devices, logic devices, etc., such as DRAM and SRAM, etc., are constituted with a very large number of elements, and often parts of the circuits and memory cells do not normally operate due to various factors caused in the fabrication processes. In such case, if the devices are treated as defects because of the defective partial circuits or memory cells, it will decrease the fabrication yields and lead to the fabrication cost increase. As a counter measure to this, in the recent semiconductor devices, the defective circuits and defective memory cells are changed over to redundant circuits and redundant memory cells which have bee prepared in advance to make the defective circuits normal to thereby remedy the defective devices.

Furthermore, semiconductor devices which are each fabricated with a plurality of circuits having different functions as a whole to change over the functions of the devices, or semiconductor devices which are fabricated with prescribed circuits to have the device characteristics adjusted are available are exist.

The reconstitution of such a semiconductor device is made usually by mounting a fuse circuit having a plurality of fuses mounted in the semiconductor device and disconnecting the fuses by irradiating laser beams after operation tests, etc.

Generally, the fuses are formed of the same conducting layers forming the interconnections and pads forming the internal circuits of a semiconductor device, and for the purpose of protecting the semiconductor device from moisture, a cover film is formed on the fuses. The fuses are usually disconnected after the cover film has been formed.

The fuses have been conventionally disconnected by the following method.

In a first method, laser beams are irradiated onto the cover film to disconnect the fuses. The first method allows the semiconductor device to be fabricated without increasing the fabrication steps. However, because of the thick cover film remaining on the fuses, high laser energy is required to disconnect the fuses. Resultantly, large craters are generated, the silicon substrate is melted, causing cracks, cracks extended downward from the disconnection part of the fuses, and other damages are caused. These are problems.

In a second method, the cover film on the fuses is etched thin, and laser beams are irradiated onto the thinned cover film to disconnect the fuses. The second method may use lower laser energy and can decrease the generation of craters and the damages to the base in comparison with the first method. However, the etching of the cover film must be stopped enroute, which makes it difficult to control the etching amount. In thinning the cover film, there is a risk that the fuses may be exposed. Resultantly, the disadvantages that the reliability is decreased, and the barrier metal of bumps is formed even on the fuses in the bump forming step, and other disadvantages are caused.

In a third method, after the cover film or the inter-layer insulating film have been etched to exposed the fuses, a thin protection film is formed, and laser beams are irradiated onto the protection film to disconnect the fuses. The third method never exposes the fuses, and the reliability is increased. The protection film can be easily formed thin. The third method is described in, e.g., Reference 1 (Japanese published unexamined patent application No. Hei 03-044062) and Reference 2 (Japanese published unexamined patent application No. 2001-250867).

### SUMMARY OF THE INVENTION

In Reference 1 and Reference 2, in the etching for exposing the fuses, the cover film or the inter-layer insulating film is etched until the side surfaces of the fuses are completely exposed. This is because the stress exerted in disconnecting the fuses is hindered from affecting the fuses adjacent thereto.

However, when the cover film or the inter-layer insulating film is etched until the side surfaces of the fuses are completely exposed, the fuses, which are not supported at the side surfaces, the patterns of the fuses often collapse or are scattered in the cleaning step following the etching. Especially, the inter-layer insulating film directly below the fuses is side-etched, and the fuses overhang, the pattern collapse and the pattern scatter tend to take place. In later steps, the fuses are often cracked by stressed exerted by filling resins, as of the under fill, etc. for adhering the chips to the substrate, stresses exerted by the substrate after mounted, etc. These phenomena are conspicuous especially in the fuses of large aspect ratios and downsized fuses.

As described in Reference 2, deep cavities are formed between the fuses, in the later bump forming step, the barrier metal, such as titanium or others, or the dry film resist, used in forming the bumps by printing, often remain on the side surface of the fuses, which often hinders the fuse disconnecting. Such residues on the side surfaces of the fuses are especially conspicuous when the pitch of the fuses is small, which can be a factor to hindering the reduction of the fuse pitch, i.e., the downsizing of semiconductor devices.

An object of the present invention is to provide a semiconductor device comprising fuses which can be formed without the pattern collapse and the pattern scatter and can be disconnected stably with low laser energy and can be arranged at a small pitch, and a method for fabricating the semiconductor device.

According to one aspect of the present invention, there is provided a semiconductor device comprising: an inter-layer insulating film formed over the semiconductor substrate; a fuse buried in the inter-layer insulating film; and a cover film formed over the inter-layer insulating film and having an opening formed down to the fuse, the inter-layer insulating film being formed in contact with a side wall of the fuse in the opening.

According to another aspect of the present invention, there is provided a method for fabricating a semiconductor device comprising the steps of: forming over a substrate a fuse buried in an inter-layer insulating film; forming a cover film over the inter-layer insulating film; and forming an opening in the cover film down to the fuse, leaving the inter-layer insulating film on at least a part of a side wall of the fuse in the opening.

According to the present invention, the inter-layer insulating film is formed in contact with the sidewall of the fuse in the opening where laser beam is to be irradiated for disconnecting the fuses, whereby the fuse is supported with the inter-layer insulating film. Resultantly, the pattern collapse and the pattern scatter of the fuses in the cleaning following the etching step of forming the opening can be prevented. The direction of the fuses scattering when the fuses are exploded can be restricted in the vertical direction. Resultantly, the wide scatter of the fuses can be prevented, which permits the fuses to be arranged at a small pitch, and the fuser region can be reduced.

The inter-layer insulating film is formed on the sidewall of the fuse in the opening, whereby the step between the surface of the fuse and the surface of the inter-layer insulating film can be made small. Forming the inter-layer insulating film, covering the entire sidewall of the fuse can make the surface substantially flat in the opening. Resultantly, the generation of residues of the barrier metal in the later bump forming step in the region where laser beam is irradiated for disconnecting the fuses and the generation of residues of the dry film resist in the mounting step can be suppressed. Thus, no residue hinders the disconnection of the fuses.

The fuse protection film is formed after the opening has been formed, whereby the film thickness of the fuse protection film can be easily controlled to be thin. Resultantly, the fabrication process can be simplified, and the fuses can be stably disconnected.

### BRIEF DESCRIPTION OF THE DRAWINGS

FIG. 1A is a plan view of the semiconductor device according to a first embodiment of the present invention, which shows the structure thereof.

FIGS. 1B and 1C are sectional views of the semiconductor device according to the first embodiment of the present invention, which show the structure thereof.

FIG. 2 is a schematic sectional view of the semiconductor device according to the first embodiment of the present invention, which shows the structure thereof.

FIGS. 3A-3E and 4A-4C are sectional views of the semiconductor device according to the first embodiment of the present invention in the step of the method for fabricating the same, which show the method.

FIG. 5 is a sectional view of the semiconductor device according to one modification of the first embodiment of the present invention, which shows a structure thereof.

FIG. 6A is a plan view of the semiconductor device according to a second embodiment of the present invention, which shows the structure thereof.

FIGS. 6B and 6C are sectional views of the semiconductor device according to the second embodiment of the present invention, which show the structure thereof.

FIGS. 7A-7C and 8A-8C are sectional views of the semiconductor device according to the second embodiment of the present invention in the steps of the method for fabricating the same, which show the method.

FIGS. 9 and 10 are sectional views of the semiconductor devices according to modifications of the embodiments of the present invention and the method for fabricating the same, which show the structures thereof.

### DETAILED DESCRIPTION OF THE INVENTION

### A FIRST EMBODIMENT

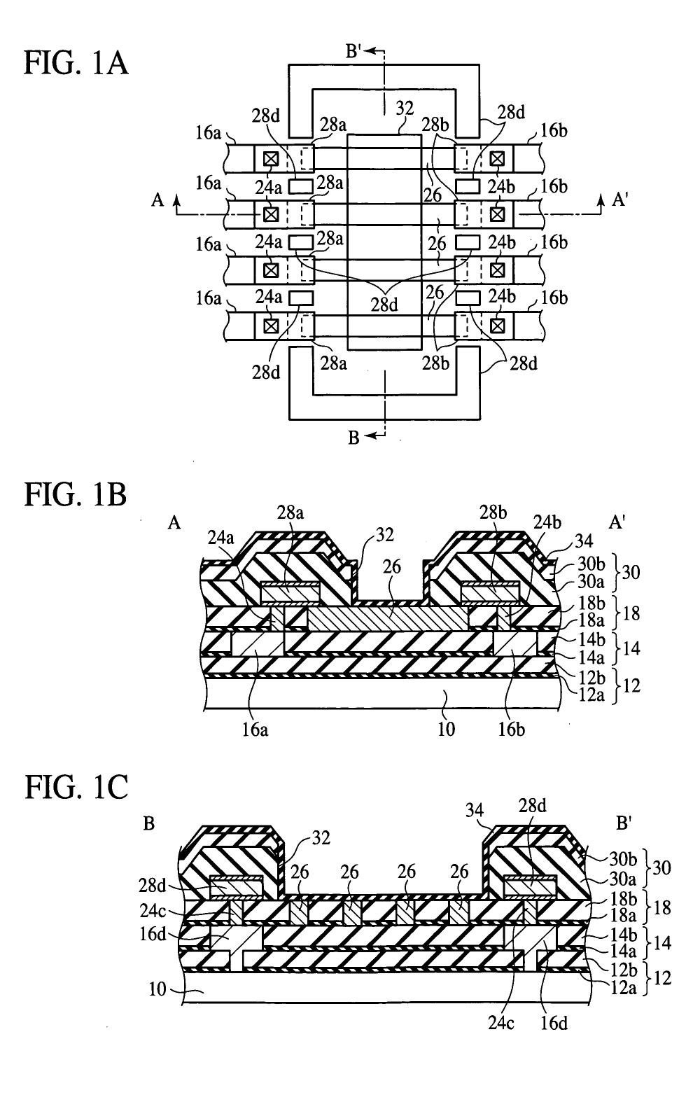

The semiconductor device and the method for fabricating the same according to a first embodiment of the present invention will be explained with reference to FIGS. 1 to 4C.

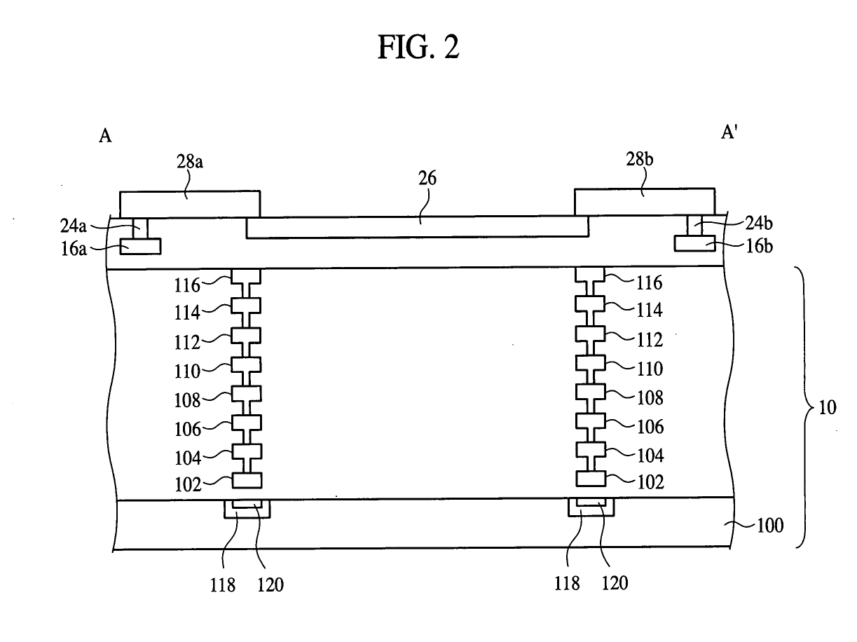

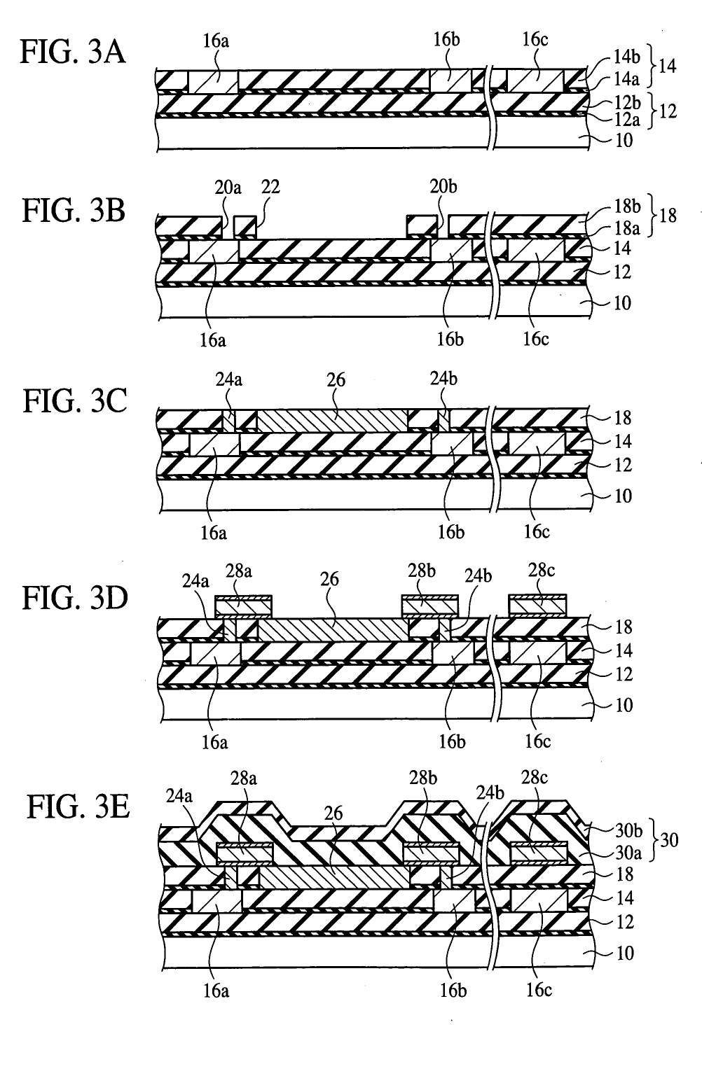

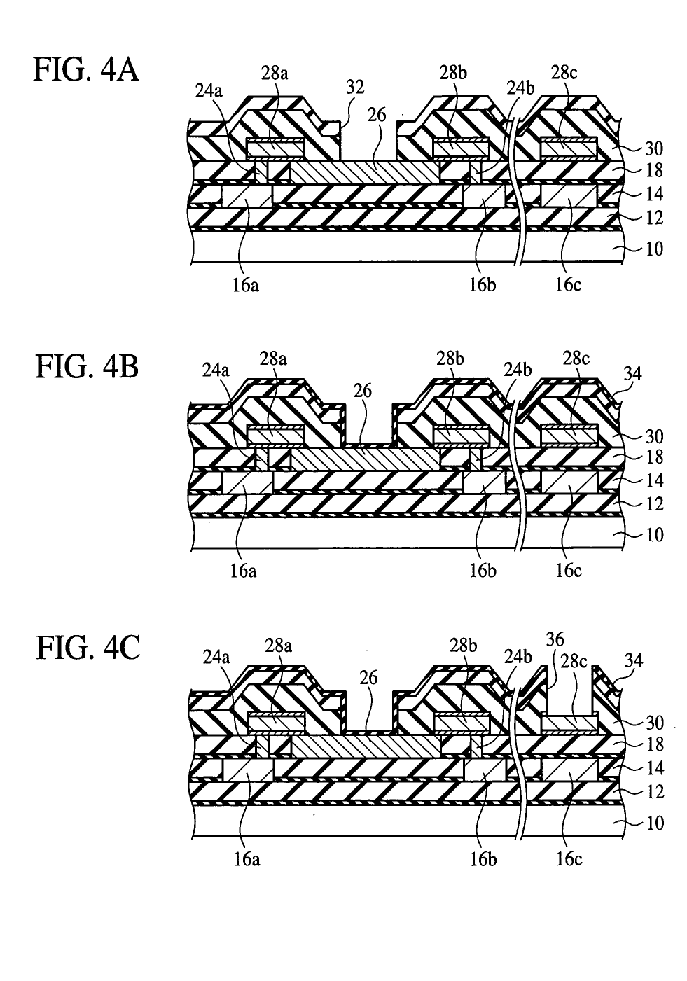

FIGS. 1A-1C are a plan view and sectional views of the semiconductor device according to the present embodiment, which show the structure thereof. FIG. 2 is a schematic view of the semiconductor device according to the present embodiment, which shows the structure thereof. FIGS. 3A-3E and 4A-4C are sectional views of the semiconductor device according to the present embodiment in the steps of the method for fabricating the same, which show the method.

First, the structure of the semiconductor device according to the present embodiment will be explained with reference to FIGS. 1A-1C and 2. FIG. 1A is a plan view of the semiconductor device according to the present embodiment, which shows the structure thereof. FIG. 1B is the sectional view along the line A-A′ in FIG. 1. FIG. 1C is the sectional view along the line B-B′ in FIG. 1.

As shown in FIGS. 1B and 1C, an inter-layer insulating film 12 including an SiC film 12a and an SiO film 12b is formed on a substrate 10. In this specification, the substrate includes not only a semiconductor substrate itself, but also the substrate with elements, such as transistors, etc. and 1, or 2 or more interconnection layers formed on the semiconductor substrate. The inter-layer insulating film is an insulating film for insulates the interconnection layers on different levels.

On the inter-layer insulating film 12, an inter-layer insulating film 14 of an SiC film 14a and an SiO film 14b is formed. Interconnection layers 16a, 16b, 16d are buried in the inter-layer insulating film 14.

An inter-layer insulating film 18 of an SiC film 18a and an SiO film 18b is formed on the inter-layer insulating film 14 with the interconnection layers 16a, 16b, 16d buried in. A contact plug 24b electrically connected to the interconnection layer 16a, a contact plug 24b electrically connected to the interconnection layer 16b, a contact plug 24c electrically connected to the interconnection layer 16d, and a fuse 26 are buried in the inter-layer insulating film 18.

An interconnection layer 28a electrically interconnecting the contact plug 24a and one end of the fuse 26, an interconnection layer 28b electrically interconnecting the contact plug 24b and the other end of the fuse 26, and an interconnection layer 28d electrically connected to the interconnection layer 16d are formed on the inter-layer insulating film 18 with the contact plugs 24a, 24b, 24c and the fuse 26 buried in.

A cover film 30 of an SiO film 30a and an SiN film 30b is formed on the inter-layer insulating film 18 with the interconnection layers 28a, 28b, 28d formed on. An opening 32 is formed in the cover film 30 down to the fuse 26. The cover film is an insulating film formed on the uppermost interconnection layer and is formed for the purpose of protecting the semiconductor device from moisture, etc. The general structure of the cover film is the layer structure of an SiO film and an SiN film, as in the present embodiment.

A fuse protection film 34 of an SiN film is formed in the opening 32 and on the cover film 30.

As shown in FIG. 1A, a plurality of the fuses 26 are formed in the region where the opening 32 is formed. As shown in FIG. 1C, in the opening 32, the side surfaces of the fuses 26 are covered with the inter-layer insulating film 18, and the height of the upper surfaces of the fuses 26 and the height of the upper surface of the inter-layer insulating film 18 in the opening 32 are substantially equal to each other.

As shown in FIG. 1A, the region where the fuses 26 are formed is surrounded by the inter-connection layer 28d. The inter-connection layer 28d forms a part of the so-called a guard ring, a seal ring, a moisture resistant ring or others. The guard ring is for prohibiting the intrusion of moisture, water, etc. into the semiconductor device from the fuse circuit region and is usually formed of ring-patterned interconnection layers stacked thickness-wise one on another, which are all the layers from the metal interconnection layer of the first level to the upper most level interconnection layer and are interconnected through groove-shaped via-holes.

In a semiconductor device including 10 metal interconnection layers, for example, as exemplified in FIG. 2, ring-shaped interconnection layers 102, 104, 106, 108, 110, 112, 114, 116 are formed interconnected through groove-shaped via-holes are formed over an impurity diffused layer 120 in an n-well 118 formed in a silicon substrate 10. In this case, the lower structure up to the interconnection layer 116 from the silicon substrate corresponds to the substrate 10 in FIGS. 1A and 1B.

The layers upper of the interconnection layer 116 (the interconnection layers 16d, 28d) cannot be stacked in a ring shape so as to ensure the electric path to the fuses 26. Accordingly, as exemplified in FIG. 1A, the interconnection layers 16d, 28d have the ring shape which is interrupted at the respective leads of the interconnection layers 28a, 28b. That is, as viewed in the sectional view along the line A-A′ in FIG. 1A, the guard ring is formed of the interconnection layers 102-116 as shown in FIG. 2, and as viewed in the sectional view along the line B-B′ in FIG. 1, the guard ring is formed of the interconnection layers 102-116 and the interconnection layers 16d, 28d as shown in FIGS. 1C and 2.

As described above, one characteristic of the semiconductor device according to the present embodiment is that the inter-layer insulating film 18 is formed in contact with the side surfaces of the fuses 26 in the opening 32, which is the region where laser beams are to be irradiated to for disconnecting the fuses. The fuses 26 are thus supported by the inter-layer insulating film 18, whereby the pattern collapse and pattern scatter of the fuses 26 can be prevented in cleaning step following the etching step for forming the opening 32.

The pattern collapse and pattern scatter of the fuses 26 are conspicuous when the inter-layer insulating film 14 below the fuses is etched horizontally, and the fuses 26 overhang. Accordingly, it is preferably to take into account a process margin so that parts of the side surfaces of the fuses are covered with the inter-layer insulating film 18.

The inter-layer insulating film 18 formed in contact with the side surfaces of the fuses 26 has the effect of restricting the scattering direction of the fuses 26 when the fuses 26 are exploded to the vertical direction. The fuses 26 are thus prevented from widely scattering, which permits the fuses 26 to be arranged at a small pitch, and the fuse regions can be smaller.

It is preferable in view of supporting the fuses 26 that the inter-layer insulating film 18 is formed in contact with at least parts of the side surfaces of the fuses 26.

In addition to forming the inter-layer insulating film 18 in contact with the side surfaces of the fuses 26, it is more effective to even the upper surfaces of the fuses 26 with the surface of the inter-layer insulating film 18 in the opening 32. That is, the height of the upper surfaces of the fuses 26 and the height of the surface of the inter-layer insulating film 18 in the opening 32 are made substantially equal to each other, whereby no fine concavities and convexities take place in the opening 32. Accordingly, the residues of a barrier metal in the laser beam application region for disconnecting the fuses can be suppressed in the later bump forming step, and the residues of the dry film resist can be suppressed in the mounting step. Thus, no residue hinders the disconnection of the fuses.

The upper surfaces of the fuses 26 and the surface of the inter-layer insulating film 18 in the opening 32 are not essentially even with each other. They maybe even to an extent that the residues do not take place in the later steps, i.e., may be substantially even with each other.

The fuse protection film 34 for covering the fuses 26 in the opening 32 is formed after the opening 32 has been formed, and the film thickness can be easily controlled. The fuse protection film 34 may be thinner than the cover film 30. Accordingly, the fabrication process can be simplified, and the disconnection of the fuses 26 can be stable.

Then, the method for fabricating the semiconductor device according to the present embodiment will be explained with reference to FIGS. 3A-4C. FIGS. 3A-3E and 4A-4C are sectional views of the part corresponding to the section along the line A-A′ in FIG. 1A and the pad opening in the steps of the method for fabricating the semiconductor device. The drawings on the left side of the respective drawings are the section corresponding to the part corresponding to the section along the line A-A′ in FIG. 1A, and the drawings on the right side of the respective drawings are section of the pad opening region.

First, the SiC film 12a of, e.g., a 30 nm-thick and the SiO film of, e.g., a 560 nm-thick are deposited on the substrate 10 by, e.g., CVD method to form the inter-layer insulating film 12 of the SiC film 12a and the SiO film 12b.

Next, the SiC film 14a of, e.g., a 30 nm-thick and the SiO film 14b of, e.g., a 870 nm-thick are deposited on the inter-layer insulating film 12 by, e.g., CVD method to form the inter-layer insulating film 14 of the SiC film 14a and the SiO film 14b.

Then, the interconnection layers 16a, 16b, 16c formed of a conducting layer of mainly copper are formed, buried in the inter-layer insulating film 14 by damascene process (FIG. 3A).

Then, the SiC film 18a of, e.g., a 30 nm-thick and the SiO film 18b of, e.g., a 530 nm-thick are deposited by, e.g., CVD method on the inter-layer insulating film 14 with the interconnection layers 16a, 16b, 16c buried in to form the inter-layer insulating film 18 of the SiC film 18a and the SiO film 18b.

Next, by photolithography and dry etching, in the inter-layer insulating film 18, contact holes 20a, 20b, and an interconnection groove 22 are formed respectively down to the interconnection layers 16a, 16b and in the region where a fuse is to be formed (FIG. 3B).

Then, a 50 nm-thick titanium nitride film as the barrier metal, and a tungsten film of, e.g., a 300 nm-thick are deposited respectively by, e.g., sputtering method and by CVD method and are etched back or polished back until the surface of the inter-layer insulating film 18 is exposed to thereby form the contact plugs 24a, 24b buried in the contact holes 20a, 20b and formed of the conducting layer mainly of tungsten and the fuse 26 buried in the interconnection groove 22 and formed of the conducting layer mainly of tungsten (FIG. 3C).

Next, a 60 nm-thick titanium film, a 30 nm-thick titanium nitride film, a 1000 nm-thick Al—Cu film and a 50 nm-thick titanium nitride film, for example, are deposited by, e.g., sputtering method on the inter-layer insulating film 18 with the contact plugs 24a, 24b and the fuses 26 buried in.

Next, the stacked film of the titanium nitride film/Al—Cu film/titanium nitride film/titanium film is patterned to form the interconnection layers 28a, 28b, 28c formed of the stacked film (FIG. 3D). Thus, the interconnection layer 16a is electrically connected to one end of the fuse 26 via the contact plug 24a and the interconnection layer 28a, the interconnection layer 16b is electrically connected to the other end of the fuse 26 via the contact plug 24b and the interconnection layer 28b. The interconnection layer 28c can be used as, e.g., a pad electrode.

Next, the SiO film 30a of, e.g., a 1400 nm-thick and the SiN film 30b of, e.g., a 500 nm-thick are deposited by, e.g., CVD method on the inter-layer insulating film 18 with the interconnection layers 28a, 28b, 28c formed on to form the cover film 30 of the SiC film 30a and the SiN film 30b.

Then, the cover film 30 is etched by photolithography and dry etching to form the opening 32 in the cover film 30 down to the fuse 26 (FIG. 4A). At this time, the opening 32 is formed, exposing a plurality of the fuses 26 in the opening 32. It is preferable to control the etching of the cover film so that the height of the surface of the inter-layer insulating film 18 and the height of the upper surfaces of the fuses 26 in the opening 32 are substantially equal to each other (refer to FIG. 1C).

The opening is thus arranged, whereby no fine concavities and convexities are formed in the opening 32, and resultantly, in the region for laser beams to be irradiated to for the disconnection of the fuses, the generation of residues of the barrier metal in the later bump forming step and the generation of residues of the dry film resist in the mounting step can be suppressed.

Then, a 50 nm-thick SiN film, for example is deposited by, e.g., CVD method on the cover film 30 with the opening 32 formed in to form the fuse protection film 34 of the SiN film (FIG. 4B). It is preferable to set the thickness of the fuse protection film 34 at not more than 350 nm. When the film thickness is more than 350 nm, there are risks that the yield of disconnecting the fuse will be lowered, and high laser energy will be required, resultantly generating large craters.

Then, the fuse protection film 34 and the cover film 30 are etched by photolithography and dry etching to form a pad opening 36 for exposing the interconnection layer 28c (FIG. 4C).

Next, circuit tests, etc. A remade, and then as required, prescribed fuses 26 are disconnected. When the fuse protection film 34 has a 50 nm-thick, the fuses 26 having a 600 nm-thick and a 400 nm-width are arranged at a 5 μm-pitch, laser beams of, e.g., a 1.3 μm-wavelength and a 0.35-0.9 μJ-energy are irradiated, and the fuses 26 can be disconnected through the fuse protection film 34.

In the semiconductor device having the above-described structure, the fuses were disconnected under the above-described conditions, and the fuses could be disconnected with good yields. After the fuses were disconnected, moisture resistance test was made. The fuses had good moisture resistance, and very high reliability could be obtained.

As described above, according to the present embodiment, the inter-layer insulating film is formed in contact with the side walls of the fuses in the opening which is the region for laser beams to be irradiated for the disconnection of the fuses, whereby the fuses are supported by the inter-layer insulating film. In the cleaning step following the etching step for forming the openings, the pattern collapse and the pattern scatter of the fuse can be prevented. Furthermore, when the fuses are exploded, the scattering direction of the fuses can be restricted in the vertical direction, which permits the fuses to be arranged at a small pitch, and the fuse region can be reduced.

The inter-layer insulating film is left on the side walls of the fuses in the opening, whereby steps can be deceased. This can suppress, in the region for laser beams to be irradiated for the disconnection of the fuses, the generation of residues of the barrier metal in the later bump forming step and the generation of residues of the dry film resist in the mounting step. Thus, no residue hinders the disconnection of the fuses.

The fuse protection film is formed after the opening has been formed, whereby the thickness of the fuse protection film can be easily controlled thin. Accordingly, the fabrication process can be simplified, and the disconnection of the fuses can be stably performed.

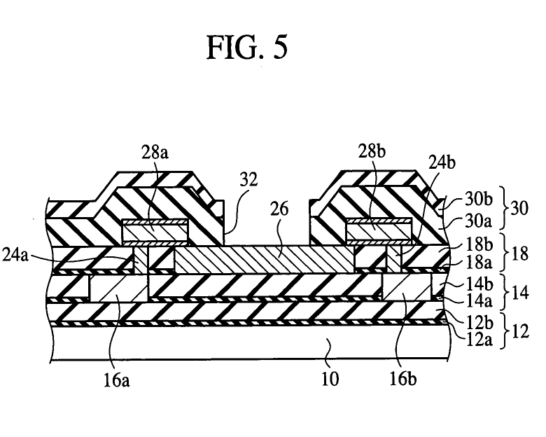

In the present embodiment, the fuse protection film 34 is formed in the opening 32 and on the cover film 30. However, the fuse protection film 34 is not essential when the bump forming step is not necessary (refer to FIG. 5). Inventors of the present application made the moisture resistance test after the fuses have been disconnected. The result was inferior to the result of the moisture resistance test with the fuse protection film 34. However, without the fuse protection film 34, the moisture resistance was sufficient.

### A SECOND EMBODIMENT

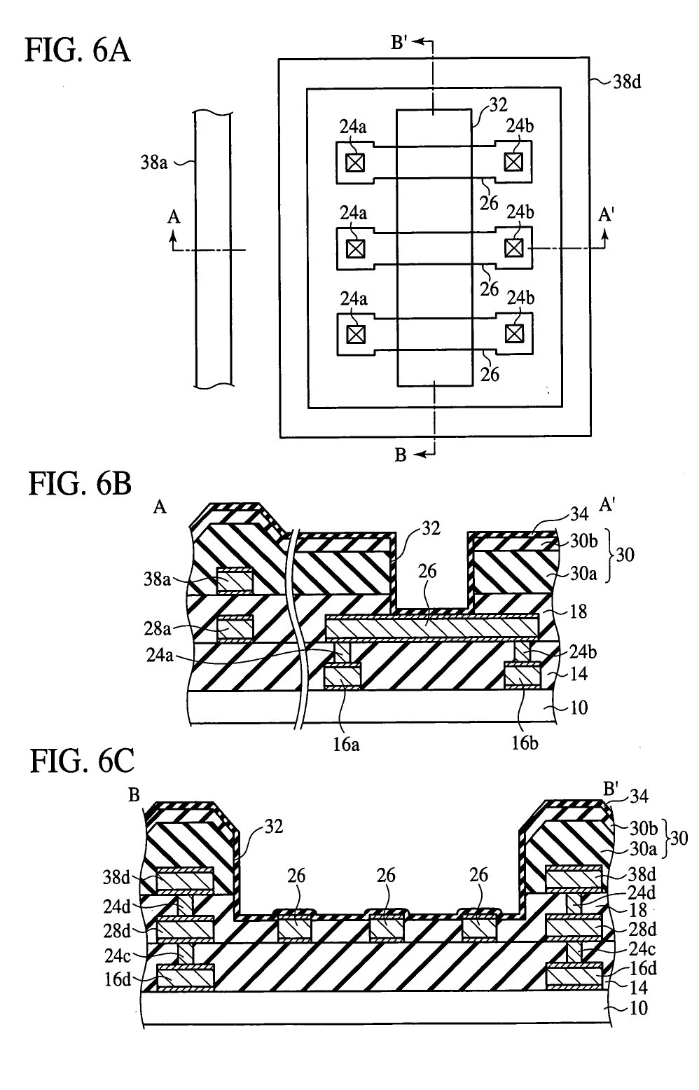

The semiconductor device and the method for fabricating the same according to a second embodiment of the present invention will be explained with reference to FIGS. 6A to 8C. The same members of the present embodiment as those of the semiconductor device according to the first embodiment shown in FIGS. 1A to 5 are represented by the same reference numbers not to repeat or to simplify their explanation.

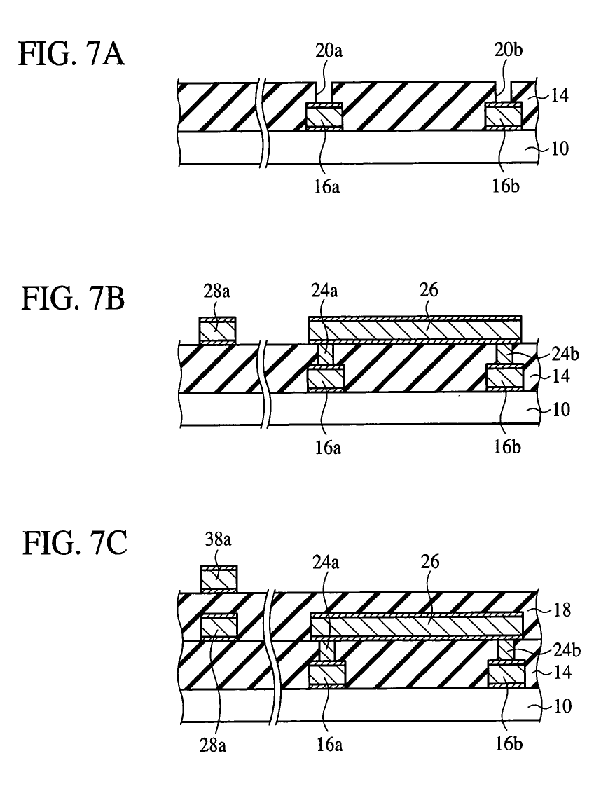

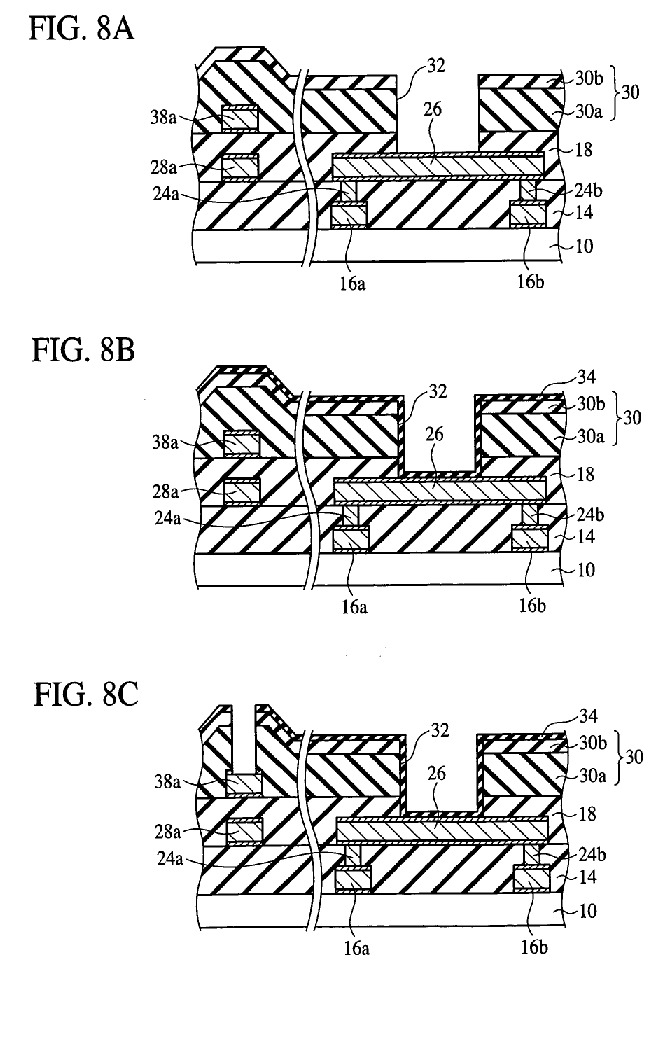

FIGS. 6A-6C are a plan view and sectional views of the semiconductor device according to the present embodiment, which show the structure thereof. FIGS. 7A-8C are sectional views of the semiconductor device according to the present embodiment in the steps of the method for fabricating the same, which show the method.

In the first embodiment described above, the present invention is applied to a semiconductor device comprising the fuses formed concurrently with the contact plugs by the so-called damascene process. However, the present invention is applicable to a semiconductor device comprising fuses formed by patterning a conducting film by photolithography and dry etching. The present embodiment is one example of the application of the present invention to such the semiconductor device.

First, the structure of the semiconductor device according to the present embodiment will be explained with reference to FIGS. 6A-6C. FIG. 6A is a plan view of the semiconductor device according to the present embodiment, which shows the structure thereof. FIG. 6B is the sectional view along the line A-A′ in FIG. 6A. FIG. 6C is the sectional view along the line B-B′ in FIG. 6A.

As shown in FIGS. 6B and 6C, interconnection layers 16a, 16b, 16d are formed on a substrate 10.

An inter-layer insulating film 14 of an SiO film is formed on the substrate 10 with the interconnection layers 16a, 16b, 16d formed on. Contact plugs 24a, 24b, 24c electrically connected to the interconnection layers 16a, 16b, 16d are buried in the inter-layer insulating film 14.

On the inter-layer insulating film 14 with the contact plugs 24a, 24b, 24c buried in, a fuse 26 having one end electrically connected to the contact plug 24a and the other end electrically connected to the contact plug 24b, an interconnection layer 28d connected to the interconnection layer 16d via the contact plug 24c, and an interconnection layer 28a are formed.

An inter-layer insulating film 18 of an SiO film is formed on the inter-layer insulating film 14 with the fuse 26 and the interconnection layers 28a, 28d formed on. The contact plug 24d connected to the interconnection layer 28d is buried in the inter-layer insulating film 18.

An interconnection layer 38a and an interconnection layer 38b connected to the interconnection layer 28d via the contact plug 24d are formed on the inter-layer insulating film 18 with the fuse 26, the interconnection layers 28a, 28d and the contact plug 24d buried in.

A cover film 30 of an SiO film 30a and an SiN film 30b is formed on the inter-layer insulating film 18 with the interconnection layers 38a, 38b formed on. An opening 32 is formed in the cover film 30 and the inter-layer insulating film 18 down to the fuse 26. A fuse protection film 34 of an SiN film is formed in the opening 36 and on the cover film 30.

As shown in FIG. 6A, a plurality of the fuses 26 are formed in the region where the opening 32 is formed. As shown in FIG. 6C, in the opening 32, the side surfaces of the fuses 26 are covered with the inter-layer insulating film 18, and the upper surfaces of the fuses 26 and the surface of the inter-layer insulating film 18 in the opening 32 are substantially even to each other.

As shown in FIGS. 6A and 6C, the region where the fuses 26 are formed is surrounded by the interconnection layers 16d, 28d, 38d. The interconnection layers 16d, 28d, 38d constitute a part of a guard ring. The guard ring can have the same constitution as that of the semiconductor device according to the first embodiment exemplified in FIG. 2.

As described above, one characteristic of the semiconductor device according to the present embodiment is that the inter-layer insulating film 18 is formed in contact with the side surfaces of the fuses 26 in the opening 32, which is the region for laser beams to be irradiated to for disconnecting the fuses. The fuses 26 are thus supported with the inter-layer insulating film 18, whereby the pattern collapse and the pattern scatter of the fuses 26 in the cleaning step following the etching step for forming the opening 32 can be prevented.

The inter-layer insulating film 18 is formed in contact with the side surfaces of the fuses 26, whereby the effect of restricting the scattering direction of the fuses 26 when the fuses 26 are exploded to the vertical direction is also produced. The fuses 26 are thus hindered from widely scattering, which permits the fuses to be arranged at a small pitch, and the fuse region can be small.

It is preferable in view of supporting the fuses 26 that the inter-layer insulating film 18 is formed in contact with at least parts of the side surfaces of the fuses 26.

In addition to forming the inter-layer insulating film 18 in contact with the side surfaces of the fuses 26, it is more effective to even the upper surfaces of the fuses 26 with the surface of the inter-layer insulating film 18 in the opening 32. That is, the height of the upper surfaces of the fuses 26 and the height of the surface of the inter-layer insulating film 18 in the opening 32 are made substantially equal to each other, whereby no fine concavities and convexities take place in the opening 32. Accordingly, the residues of a barrier metal in the laser beam application region for disconnecting the fuses can be suppressed in the later bump forming step, and the residues of the dry film resist can be suppressed in the mounting step. Thus, no residue hinders the disconnection of the fuses.

The fuse protection film 34 for covering the fuses 26 in the opening 32 is formed after the opening has been formed, whereby the thickness of the fuse protection film can be easily controlled thin. Accordingly, the fabrication process can be simplified, and the disconnection of the fuses can be stably performed.

Then, the method for fabricating the semiconductor device according to the present embodiment will be explained with reference to FIGS. 7A and 8C. FIGS. 7A-7C and 8A-8C are sectional views of the parts corresponding to the section along the line A-A′ in FIG. 6A and the pad opening region in the steps of the method for fabricating the semiconductor device. The drawings on the right side of the respective drawings are the section corresponding to the part corresponding to the section along the line A-A′, and the drawings on the left side of the respective drawings are section of the pad opening region.

First, a 60 nm-thick titanium film, a 30 nm-thick titanium nitride film, a 1000 nm-thick Al—Cu film and a 50 nm-thick titanium nitride film, for example, are deposited on the substrate 10 by, e.g., sputtering method.

Next, the stacked film of the titanium nitride film/Al—Cu film/titanium nitride film/titanium film is patterned to form the interconnection layers 16a, 16b of the stacked film.

Then, on the substrate 10 with the interconnection layers 16a, 16b formed on, an SiO film is deposited by, e.g., CVD method, and the surface of the SiO film is planarized by CMP method. Thus, the inter-layer insulating film 18 of the SiO film having, e.g., a thickness on the interconnection layers 16a, 16b of a 600 nm and surface planarized is formed.

Then, the contact holes 20a, 20b are formed in the inter-layer insulating film 14 down to the interconnection layers 16a, 16b by photolithography and dry etching (FIG. 7A).

Next, a 50 nm-thick titanium nitride film as the barrier metal is formed by, e.g., sputtering method, and a tungsten film of, e.g., a 300 nm-thick is deposited by CVD method. Next, both films are etched back or polished back until the surface of the inter-layer insulating film 18 is exposed to form the contact plugs 24a, 24b buried in the contact holes 20a, 20b and formed mainly of tungsten.

Then, a 60 nm-thick titanium film, a 30 m-thick titanium nitride film, a 1000 nm-thick Al—Cu film and a 50 nm-thick titanium nitride film, for example, are deposited by, e.g., sputtering method on the inter-layer insulating film 14 with the contact plugs 24a, 24b buried in.

Then, the stacked film of the titanium nitride film/Al—Cu film/titanium nitride film/titanium film is patterned to form a fuse 26 formed of the stacked film and having one end electrically connected to the interconnection layer 16a via the contact plug 24a and the other end electrically connected to the interconnection layer 16b via the contact plug 24b, and the interconnection layer 28a are formed (FIG. 7B).

Next, an SiO film is deposited by, e.g., CVD method on the inter-layer insulating film 14 with the fuse 26 and the interconnection layer 28a formed on, and the surface of the SiO film is planarized by CMP method. Thus, the inter-layer insulating film 18 formed of the SiO film having the surface planarized and having a film thickness on the fuse 26 and the interconnection layer 28 of, e.g., 600 nm is formed.

Next, a 60 nm-thick titanium film, a 30 nm-thick titanium nitride film, a 1000 nm-thick Al—Cu film and a 50 nm-thick titanium nitride film, for example, are deposited on the inter-layer insulating film 18 by, e.g., sputtering method.

Then, the stacked film of the titanium nitride film/Al—Cu film/titanium nitride film/titanium film is patterned to form the interconnection layer 38a of the stacked film (FIG. 7C) Then, the SiO film 30a of, e.g., a 1400 nm-thick and the SiN film 30b of, e.g., a 450 nm-thick are deposited by, e.g., CVD method on the inter-layer insulating film 18 with the interconnection layer 38a formed on to form the cover film 30 of the SiO film 30a and the SiN film 30b.

Next, the cover film 30 and the inter-layer insulating film 18 are etched to form the opening 32 in the cover film 30 and the inter-layer insulating film 18 down to the fuse 26 (FIG. 8A). At this time, the opening 32 is formed, exposing a plurality of the fuses 26 in the opening 32. It is preferable to control the etching of the cover film 30 and the inter-layer insulating film 18 so that in the opening 32, the height of the surface of the inter-layer insulating film 18 and the height of the upper surfaces of the fuses 26 are substantially equal to each other (refer to FIG. 6C).

The opening is thus arranged, whereby no fine concavities and convexities are formed in the opening 32, and resultantly the generation of residues of the barrier metal in the later bump forming step and the generation of residues of the dry film resist in the mounting step can be suppressed.

Then, a 50 nm-thick SiN film, for example, is deposited by, e.g., CVD method on the cover film 30 with the opening 32 formed in to form the fuse protection film 34 of the SiN film (FIG. 8B).

Next, a pad opening 36 is formed down to the interconnection layer 38a in the same way as in the method for fabricating the semiconductor device according to the first embodiment, as exemplified in FIG. 4C.

Next, circuit tests, etc. A remade, and then as required, prescribed fuses 26 are disconnected. When the fuse protection film 34 has a 50 nm-thick, and the fuses 26 having a 1140 nm-thick and a 900 nm-width are arranged at a 5 μm-pitch, laser beams of a 0.44-0.67 μJ-energy are irradiated, and the fuses 26 can be disconnected through the fuse protection film 34.

In the semiconductor device of the above-described structure, the fuses were disconnected under the above-described conditions, and the fuses could be disconnected with good yields. The moisture resistance test was made after the fuses were disconnected, and the moisture resistance of the fuses was good, and very high reliability was obtained.

As described above, according to the present embodiment, the inter-layer insulating film is formed in contact with the side walls of the fuses in the opening which is the region for laser beams to be irradiated for the disconnection of the fuses, whereby the fuses are supported with the inter-layer insulating film. In the cleaning step following the etching step for forming the openings, the pattern collapse and the pattern scatter of the fuse can be prevented. Furthermore, when the fuses are exploded, the scattering direction of the fuses can be restricted in the vertical direction, which permits the fuses to be arranged at a small pitch, and the fuse region can be reduced.

The inter-layer insulating film is formed on the side walls of the fuses in the opening, whereby the upper surfaces of the fuses and the surface of the inter-layer insulating film can be substantially even with each other. Thus, in the region for laser beams to be irradiated for the disconnection of the fuses, the generation of residues of the barrier metal in the later bump forming step and the generation of residues of the dry film resist in the mounting step can be suppressed. No residue hinders the disconnection of the fuses.

The fuse protection film is formed after the opening has been formed, whereby the thickness of the fuse protection film can be easily controlled thin. Accordingly, the fabrication process can be simplified, and the disconnection of the fuses can be stably performed.

In the present embodiment, the fuse protection film 34 is formed in the opening 32 and on the cover film 30. However, as in the modification of the first embodiment shown in FIG. 5, the fuse protection film 34 is not essential when the bump forming step is not necessary.

[Modifications]

The present invention is not limited to the above-described embodiments and can cover other various modifications.

For example, the structure below the fuses 26, the connections of the interconnection layers to the fuses 26 are not essentially limited to the above-described embodiments.

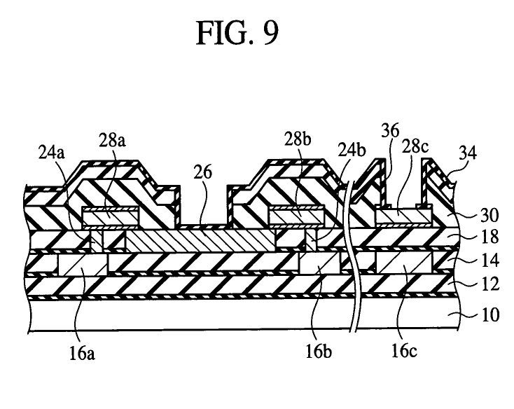

In the first and the second embodiments, the pad openings 36 are opened after the fuse protection film 34 has been formed. However, it is possible that after the opening 32 and the pad openings 36 have been formed in the cover film 30, the fuse protection film 34 is formed, and the fuse protection film 34 in the pad opening regions is removed. It is also possible that the pad openings 36 and the opening 32 down to the fuses 26 are formed separately, then the fuse protection film 34 is formed, and again the pad openings 36 are formed. When these processes are applied to the semiconductor device and the method for fabricating the same according to the first embodiment, as exemplified in FIG. 9, the fuse protection film 34 is extended to the inside walls of the pad openings 36.

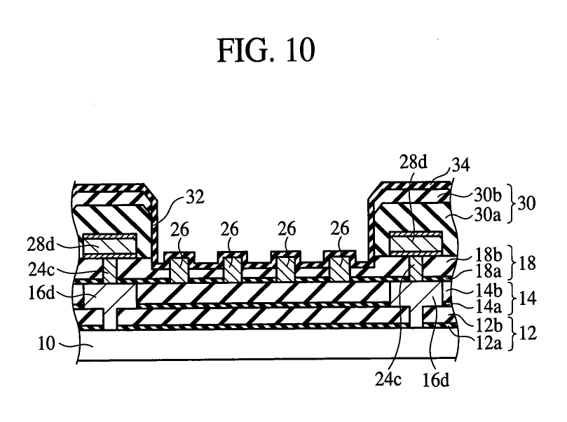

In the first and the second embodiments, in the opening 32, the upper surfaces of the fuses 26 and the surface of the inter-layer insulating film 18 are substantially equal to each other. However, in the openings 32, the upper surfaces of the fuses 26 and the surface of the inter-layer insulating film 18 are essentially equal to each other as shown in FIG. 10. The inter-layer insulating film is formed, covering at least parts of the side walls of the fuses 26, whereby the fuses 26 can be supported, and the effect of preventing the pattern collapse, the pattern scatter, etc. can be produced. Accordingly, in a case where the bump forming step is not performed, i.e., the residues which hinder the disconnection of fuses 26 are not generated in the opening 32, the surface of the inter-layer insulating film 18 is not essentially equal to the upper surfaces of the fuses 26. The inter-layer insulating film 18 is formed, covering at least parts of the side walls of the fuses, whereby the step in the opening 32 is reduced, which can suppress the generation of the residues

In the first and the second embodiments, the guard ring is provided around the fuse circuit region. However, the guard ring is not essential when the moisture resistance can be ensured by means of the fuse protection film 34, the cover film 30, etc.

In the first embodiment, the fuses are formed mainly of tungsten, and the fuses are formed mainly of aluminum in the second embodiment. However, the materials of the fuses 26 are not limited to them. For example, the fuses may be formed of copper (Cu) or titanium nitride (TiN).

In the above-described embodiments, the fuse protection film 34 is formed of SiN film. However, the material of the fuse protection film is not limited to SiN. For example, the fuse protection film 34 may be formed of SiO film or SiON film. In view of the moisture resistance, insulating films containing nitrogen, such as SiN, SiON, etc. are preferable.

1. A semiconductor device comprising:
an inter-layer insulating film formed over the semiconductor substrate;
a fuse buried in the inter-layer insulating film; and
a cover film formed over the inter-layer insulating film and having an opening formed down to the fuse,
the inter-layer insulating film being formed in contact with a side wall of the fuse in the opening.

2. A semiconductor device according to claim 1, wherein
the surface of the fuse and the surface of the inter-layer insulating film in the opening are substantially even with each other.

3. A semiconductor device according to claim 1, further comprising:
a fuse protection film formed on the fuse in the opening.

4. A semiconductor device according to claim 1, wherein
the fuse protection film is extended over the cover film.

5. A semiconductor device according to claim 3, wherein
the fuse protection film is thinner than the cover film.

6. A semiconductor device according to claim 3, wherein
the film thickness of the fuse protection film is not more than 350 nm.

7. A semiconductor device according to claim 1, wherein
a plurality of the fuses are formed in the opening.

8. A semiconductor device according to claim 1, further comprising:
a guard ring surrounding the region where the fuses are formed.

9. A method for fabricating a semiconductor device comprising the steps of:
forming over a substrate a fuse buried in an inter-layer insulating film;
forming a cover film over the inter-layer insulating film; and
forming an opening in the cover film down to the fuse, leaving the inter-layer insulating film on at least a part of a side wall of the fuse in the opening.

10. A method for fabricating a semiconductor device according to claim 9, wherein
in the step of forming the opening, the cover film is etched so that the surface of the fuse and the surface of the inter-layer insulating film in the opening are substantially even with each other.

11. A method for fabricating a semiconductor device according to claim 9, further comprising, after the step of forming the opening, the step of:
forming a fuse protection film for covering the fuse in the opening.

12. A method for fabricating a semiconductor device according to claim 11, further comprising, after the step of forming the fuse protection film, the step of:
forming a pad opening.

13. A method for fabricating a semiconductor device according to claim 9, further comprising, after the step of forming the opening, the step of:
disconnecting the fuse.

14. A method for fabricating a semiconductor device according to claim 9, wherein
the step of forming the fuse includes the step of forming the inter-layer insulating film over the substrate, the step of forming an interconnection groove in the inter-layer insulating film and the step of forming the fuse in the interconnection groove.

15. A method for fabricating a semiconductor device according to claim 9, wherein
the step of forming the fuse includes the step of forming the fuse on the substrate, and the step of forming the inter-layer insulating film, covering the fuse.

16. A method for fabricating a semiconductor device according to claim 15, further comprising the step of:
planarizing the surface of the inter-layer insulating film.
